(19) United States
(12) Patent Application Publication
(10) Pub. No.: US 2011/0045984 A1
(43) Pub. Date: Feb. 24, 2011

(54) Superconductive Compositions with Enhanced Flux Pinning

(76) Inventors: Terry G. Holesinger, Los Alamos, NM (US); David M. Feldmann, Minnetonka, MN (US)

Correspondence Address: LOS ALAMOS NATIONAL SECURITY, LLC, LOS ALAMOS NATIONAL LABORATORY, PPO. BOX 1663, LC/IP, MS A187, LOS ALAMOS, NM, 87545, US

(21) Appl. No.: 12/850,827

(22) Filed: Aug. 5, 2010

Related U.S. Application Data
(60) Provisional application No. 61/231,603, filed on Aug. 5, 2009.

(51) Int. Cl. H01L 39/00; H01L 39/24; H01B 1/08; B05D 5/12

(52) U.S. Cl. 505/100; 505/470; 505/474; 252/520.5; 427/62; 427/596

(57) ABSTRACT

A composition of matter including a thin film of a high temperature superconductive oxide having particles randomly dispersed therein, the particles of an yttrium-barium-ruthenium oxide or of an yttrium-barium-niobium oxide is provided.

The United States government has rights in this invention pursuant to Contract No. DE-AC52-06NA25396 between the United States Department of Energy and Los Alamos National Security, LLC for the operation of Los Alamos National Laboratory.

### FIELD OF THE INVENTION

The present invention relates to high temperature superconducting thick films on polycrystalline substrates, and in particular to introducing a controlled random inclusion of non-superconducting particulates within superconductive REBa₂Cu₃O₇₋ₓ films for flux pinning enhancement.

### BACKGROUND OF THE INVENTION

Introduction of flux pinning centers in melt textured REBa₂Cu₃O₇₋ₓ (REBCO where RE is a rare earth metal such as, e.g., yttrium (Y), samarium (Sm), neodymium (Nd) and the like) is known to improve the critical current density (J_{c}) of such superconductive materials significantly. Approaches to obtain significant enhancements by incorporating nanometer sized particulates that act as flux pinning centers in REBCO thin films has also been recently demonstrated. For example, significant improvements in J_{c} have been demonstrated in the prior art in pulsed laser deposited (PLD) YBCO films with BaZrO₃ particulates (see US Published Patent Application 2006/0025310), Y₂BaCuO₅ (Y211), Y₂O₃, and Nd₂O₃.

### SUMMARY OF THE INVENTION

To achieve the foregoing and other objects, and in accordance with the purposes of the present invention, as embodied and broadly described herein, the present invention provides a composition of matter including: a thin film of a high temperature superconductive oxide having particles randomly dispersed therein, the particles comprised of an yttrium-barium-ruthenium oxide or of an yttrium-barium-niobium oxide.

### BRIEF DESCRIPTION OF THE DRAWINGS

FIG. 1 shows a digital representation of a photomicrograph of a YBCO sample prepared from a starting target containing about 9 weight percent ruthenium oxide in accordance with the present invention. Examination suggested and was noted that a secondary phase (designated as a Y—Ba—Ru—O phase based on the initial starting materials) was formed with some copper substitution and the YBCO appeared free of ruthenium. Additionally, there appeared to be a BaCu₂O, phase between particles.

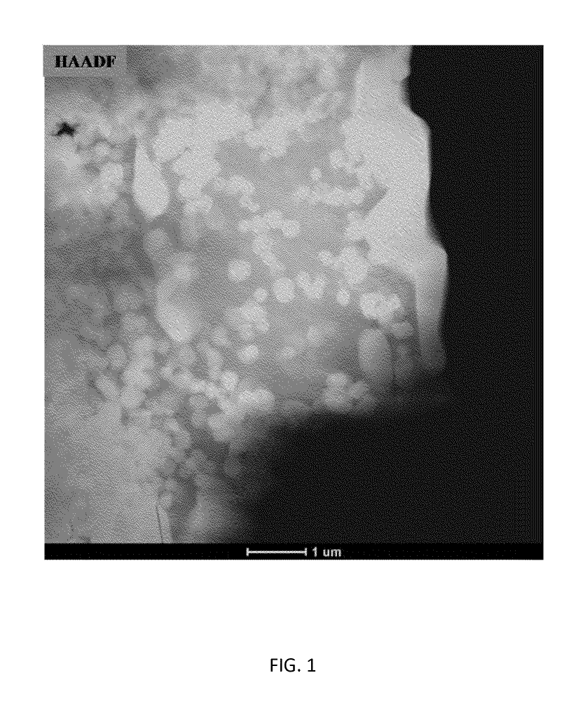

FIG. 2 shows a digital representation of a photomicrograph of a YBCO sample prepared from a starting target containing ruthenium oxide in accordance with the present invention.

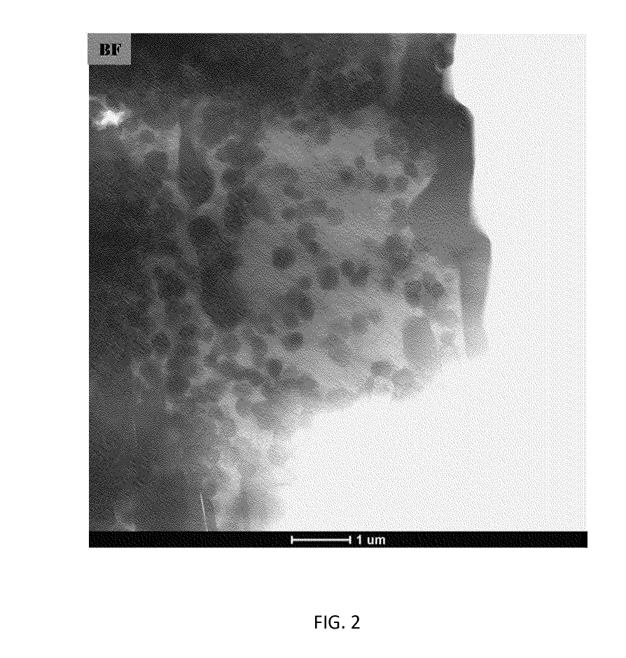

FIG. 3 shows a digital representation of a photomicrograph of a YBCO sample prepared from a starting target containing 2.5 mol percent yttrium oxide (Y₂O₃) and 5 mol percent yttrium barium ruthenium oxide (YBa₂RuO₃) ruthenium oxide in accordance with the present invention.

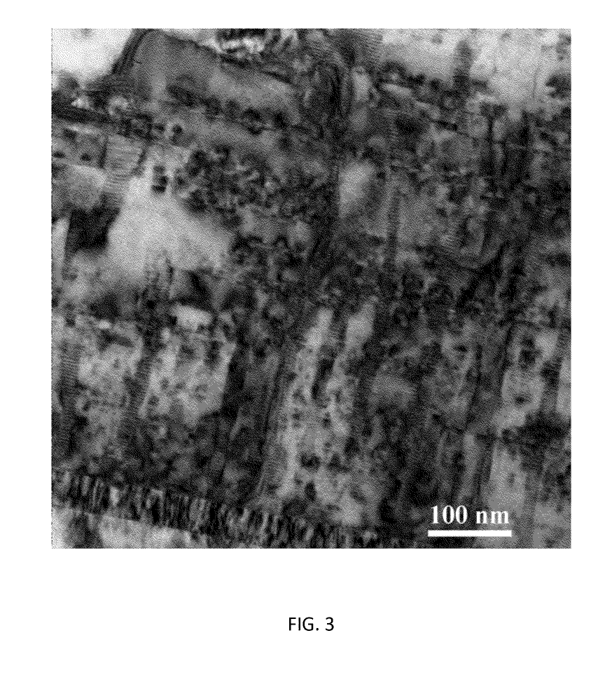

FIG. 4 shows a digital representation of a transmission electron micrograph (TEM) showing Y—Ba—Ru—O nanorods in accordance with the present invention.

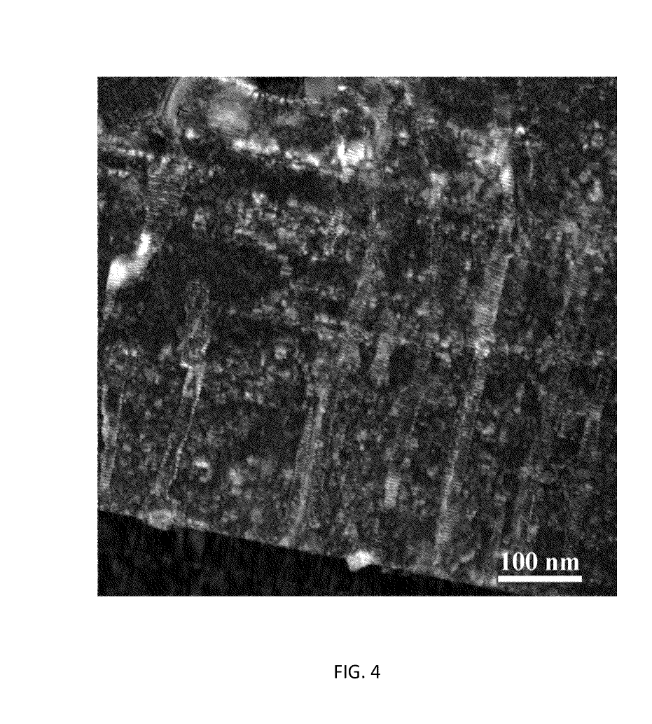

FIG. 5 shows scanning TEM Z-contrast and BF (showing both nanorods and Y₂O₃) in an embodiment of the present invention.

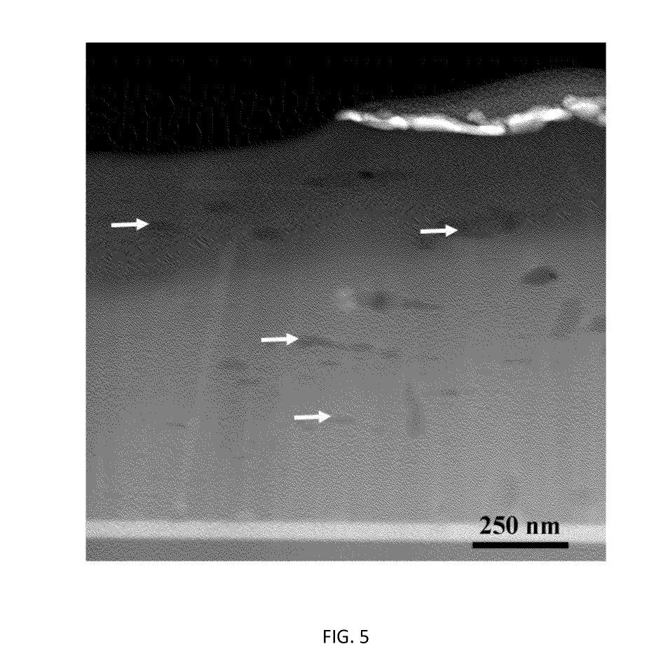

FIG. 6 shows spectral imaging showing the presence and composition of nanorods in accordance with the present invention as well as inclusions of Y₂O₃.

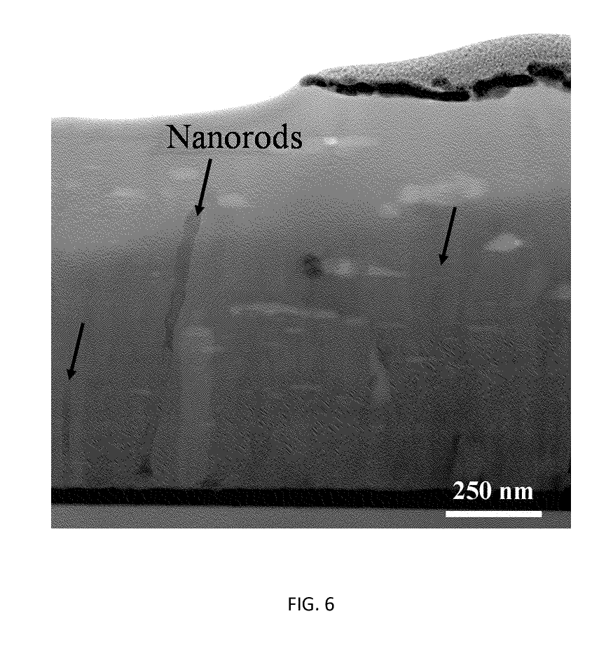

FIG. 7 shows a graph plotting thicknesses versus critical current densities (Jc) for both prior art barium zirconate additions and the ruthenium-containing particulates in accordance with the present invention.

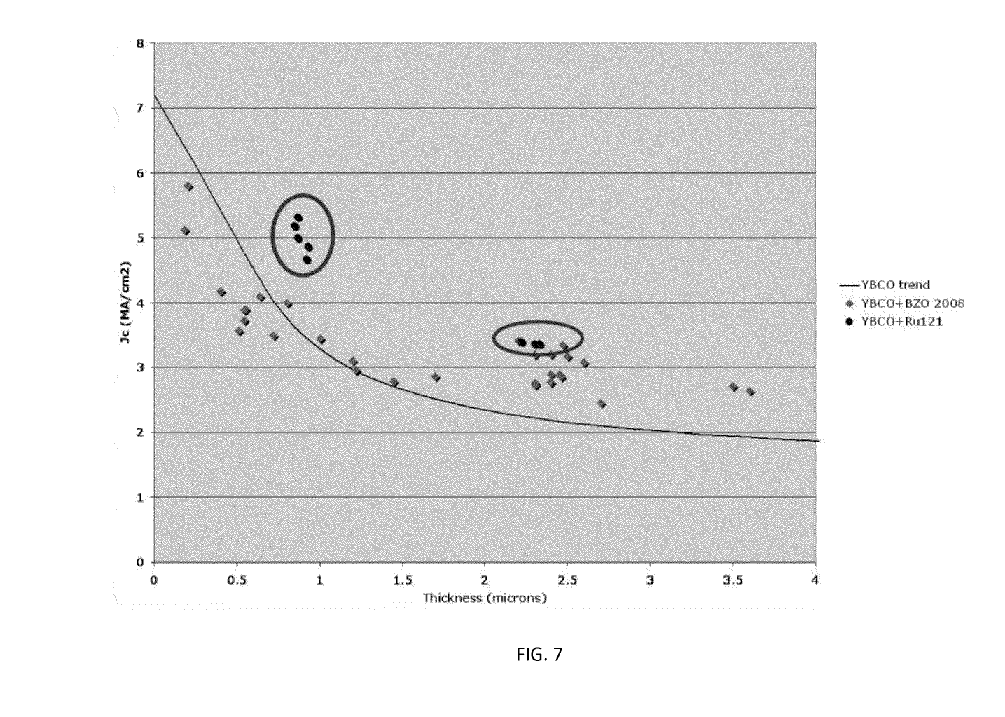

FIG. 8 shows a graph of critical current density versus theta, where theta is the angle between the film normal and the applied magnetic field of 1 T, for two preparation temperatures of films in accordance with the present invention (75.6 K).

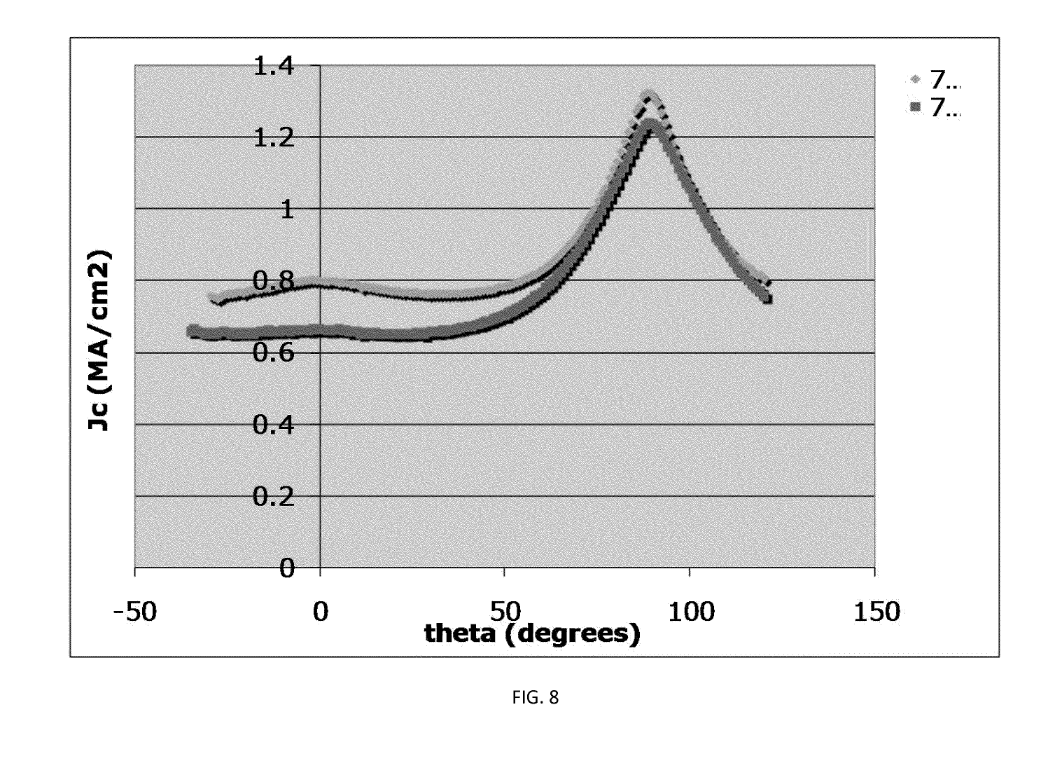

### DETAILED DESCRIPTION

The present invention is concerned with high temperature superconductive thin films including particles of a yttrium-barium-ruthenium oxide or of yttrium-barium-niobium oxide, whereby improved performance in high magnetic fields can be obtained. Such particles can be nanoparticles in size. These nanoparticles can be formed within the high temperature superconductive films during initial film formation by addition of a ruthenium compound, such as a ruthenium oxide.

In the present invention, the addition or in situ formation of a second phase material including ruthenium or niobium can lead to introduction of strain into the thin film thereby generating dislocations that can yield flux pinning within the thin film. The second phase material should not lead to substitution of elements into the high temperature superconductive material whereby the superconducting properties of the high temperature superconductive material are detrimentally diminished.

In the present invention, the high temperature superconducting (HTS) material is generally YBCO, e.g., YBa₂Cu₃O_{7-Δ}, Y₂Ba₄Cu₇O₁₄₊ₓ, or YBa₂Cu₄O₈, although other minor variations of this basic superconducting material, such as use of other rare earth metals as a substitute for some or all of the yttrium, may also be used. A mixture of the rare earth metal europium with yttrium may be one preferred combination. Other superconducting materials such as bismuth and thallium based superconductor materials may also be employed. YBa₂Cu₃O_{7-Δ} is generally preferred as the superconducting material.

High temperature superconducting (HTS) layers, e.g., a YBCO layer, can be deposited, e.g., by pulsed laser deposition or by methods such as evaporation including coevaporation, e-beam evaporation and activated reactive evaporation, sputtering including magnetron sputtering, ion beam sputtering and ion assisted sputtering, cathodic arc deposition, chemical vapor deposition, organometallic chemical vapor deposition, plasma enhanced chemical vapor deposition, molecular beam epitaxy, a sol-gel process, a solution process and liquid phase epitaxy. Post-deposition anneal processes are necessary with some deposition techniques to obtain the desired superconductivity.

In pulsed laser deposition, powder of the material to be deposited can be initially pressed into a disk or pellet under high pressure, generally above about 1000 pounds per square inch (PSI) and the pressed disk then sintered in an oxygen atmosphere or an oxygen-containing atmosphere at temperatures of about 950° C. for at least about 1 hour, preferably from about 12 to about 24 hours. An apparatus suitable for pulsed laser deposition is shown in Appl. Phys. Lett. 56, 578 (1990), “Effects of Beam Parameters on Excimer Laser Deposition of YBa₂Cu₃O_{7-Δ}”, such description hereby incorporated by reference.

Suitable conditions for pulsed laser deposition include, e.g., the laser, such as an excimer laser (20 nanoseconds (ns), 248 or 308 nanometers (nm)), targeted upon a rotating pellet of the target material at an incident angle of about 45°. The substrate can be mounted upon a heated holder rotated at about 0.5 rpm to minimize thickness variations in the resultant film or coating, The substrate can be heated during deposition at temperatures from about 600° C. to about 950° C., preferably from about 740° C. to about 765° C. where YBCO is the superconducting material. An oxygen atmosphere of from about 0.1 millitorr (mTorr) to about 10 Torr, preferably from about 100 to about 250 mTorr, can be maintained within the deposition chamber during the deposition. Distance between the substrate and the pellet can be from about 4 centimeters (cm) to about 10 cm.

The deposition rate of the film can be varied from about 0.1 angstrom per second (A/s) to about 200 A/s by changing the laser repetition rate from about 0.1 hertz (Hz) to about 200 Hz. Generally, the laser beam can have dimensions of about 1 millimeter (mm) by 4 mm with an average energy density of from about 1 to 4 joules per square centimeter (J/cm²). After deposition, the films generally are cooled within an oxygen atmosphere of greater than about 100 Torr to room temperature.

The thin films of high temperature superconducting materials are generally from about 0.2 microns to about 10 microns in thickness, more preferably in the range of from about 0.6 microns to about 2 microns.

In an embodiment of the present invention with YBCO as the high temperature superconducting (HTS) material, YBCO films including particles of yttrium-barium-ruthenium oxide, e.g., nanoparticles, provided improved performance compared with films of only YBCO, especially for coated conductor applications. While not wishing to be bound by the present explanation, it is believed that the particles of yttrium-barium-ruthenium oxide may have a composition corresponding to YBa₂RuOₓ. Generally, this may be described as an A₂BB′Oₓ phase where A is Ba, B is Ru, B′ is Y. In other options, strontium calcium and magnesium or combinations thereof may be substituted for the barium in amounts up to full substitution. Generally while B′ may be yttrium, it may also be selected from other rare earth elements, e.g, lanthanum or cerium up to lutetium (element numbers 57 through 71). Other variations may include partial substitution of ruthenium by niobium, osmium, iron, titanium, zirconium or hafnium so long as the A₂BB′Oₓ phase is retained.

Specifically, improved performance by the YBCO films of the present invention including particles of yttrium-barium-ruthenium oxide was found for operation within high magnetic fields, i.e., fields of from about 0.1 Tesla to about 10 Tesla.

In the high temperature superconducting film of the present invention, the substrate can be, e.g., any amorphous material or polycrystalline material. Polycrystalline materials can include materials such as a metal or a ceramic. Such ceramics can include, e.g., materials such as polycrystalline aluminum oxide, polycrystalline yttria-stabilized zirconium oxide (YSZ) or polycrystalline zirconium oxide. Preferably for coated conductors, the substrate can be a polycrystalline metal (e.g., metal alloys including (1) nickel-based alloys such as various Hastelloy metals, Haynes metals, and Inconel metals, (2) iron-based metals such as steels and stainless steels, or (3) copper-based metals such as copper-beryllium alloys, etc). The metal substrate on which the superconducting material is eventually deposited should preferably allow for the resultant article to be flexible whereby superconducting articles (e.g., coils, motors or magnets) can be shaped.

Other substrates such as rolling assisted biaxially textured substrates (RABiTS) may be used as well. Additionally, for still other applications, the base substrate may be a single crystal substrate such as strontium titanate, yttria-stabilized zirconium oxide (YSZ), magnesium oxide, lanthanum aluminate, or aluminum oxide.

In one embodiment, the particles including yttrium, barium and ruthenium can be incorporated into the high temperature superconductive oxide by in situ growth in a co-deposition process. Where the high temperature superconductive oxide is YBCO, precursor materials including yttrium, barium and copper are already employed in forming the final YBCO. In the process of the present invention, a precursor material including ruthenium can be included. In one approach, a precursor material providing excess barium from that needed to form a superconducting YBCO material can be included with the starting materials together with a precursor material providing ruthenium so as to allow the in situ formation of ruthenium-containing particles, e.g., particles of yttrium-barium ruthenium oxide. The precursor material providing the excess barium from that needed to form a superconducting YBCO material, can be the same precursor material used to supply the barium for the YBCO or can be a different precursor material. In another approach, the precursor materials can include those materials typically used in forming the YBCO and a precursor material providing ruthenium for the in situ formation of ruthenium-containing particles, e.g., particles of yttrium-barium ruthenium oxide. As it is known that YBCO compositions can be slightly deficient in barium content without the loss of superconducting properties, ruthenium-containing particles, e.g., particles of yttrium-barium ruthenium oxide can be formed by only the addition of ruthenium from a ruthenium containing precursor material. One suitable ruthenium containing precursor can be ruthenium oxide (RuO₂).

In the present invention, the ruthenium or niobium can be added in the form of a ruthenium or niobium metal compound such as an oxide or may be added as the metal. For example, ruthenium or niobium can be added in the form of a ruthenium or niobium compound such as ruthenium or niobium oxide or may be added as the ruthenium or niobium metal. The amount of ruthenium or niobium added can generally range from about 1 mole percent to about 10 mole percent and about 5 mole percent has be shown to yield a positive effect on flux pinning.

The measure of current carrying capacity is called “critical current” and is abbreviated as I_{c}, measured in Amperes (A), and “critical current density” is abbreviated as J_{c}, measured in Amperes per square centimeter (A/cm²).

The present invention is more particularly described in the following examples which are intended as illustrative only, since numerous modifications and variations will be apparent to those skilled in the art.

### Example 1

Initially, a bulk sample was prepared as follows. A mixed powder was made of pure YBa₂Cu₃O_{y} and RuO₂ by mixing 2 g Y123 with 0.2 g RuO₂. The material was thoroughly mixed, pressed as a pellet, and sintered at about 1000° C. for about 50 hours. The materials were prepared for SEM and STEM/TEM. Results showed a ruthenium phase that was separable from YBCO and able to be formed as an inclusion within the grains.

### Example 2

Powders of Y₂O₃, BaCO₃, CuO, RuO₂ were mixed to together for use in ball milling. The composition was Y_{1.1}Ba_{2.1}Cu_{3.0}Ru_{0.05} which is Y123 with 2.5 mol % Y₂O₃ and 5 mol % Ba₂YRuO_{y}. The powders were placed in a motorized mortar and pestle with a 10% to 90% mixture of distilled H₂O and isopropanol by volume. To this, 0.5 g of a suitable dispersant was added for keeping the powders from agglomerating during milling. The sample was milled for 4 hours. The powder slurry was removed from the mill and dried on a Schlenk line overnight. The powder was removed the next day and sintered as a loose powder at 900° C. for 25 hours, removed, and lightly ground in a glove box. For the target, about 60 g of powder was place in a 1.8″ die and the powder pressed into a disc under 15000 lbs of pressure. The target was then sintered in two stages in a furnace, the highest stage at 940° C. in pure O₂. It was removed and then used as a target in subsequent film deposition.

### Example 3

Thin film samples were prepared as follows. Ruthenium-doped films were grown by pulsed laser deposition at 775° C. to 795° C. on cerium oxide (CeO₂) buffered strontium titanate (STO) single crystals and cerium oxide (CeO₂) buffered YSZ single crystals in an ambient oxygen pressure of 200 mtorr. Film growth times were from about 20 to about 70 minutes at a laser repetition rate of 5 Hz. Laser energy entering into the chamber was approximately 200 mJ/pulse. Final film thicknesses were from about 1 micron to about 2.5 microns. Films were measured for J_{c} in liquid nitrogen at self-field and in applied fields up to 1.1 T at various field orientations.

Although the present invention has been described with reference to specific details, it is not intended that such details should be regarded as limitations upon the scope of the invention, except as and to the extent that they are included in the accompanying claims.

What is claimed is:

1. A composition of matter comprising: a thin film of a high temperature superconductive oxide having particles randomly dispersed therein, said particles comprised of a yttrium-barium-ruthenium oxide or of a yttrium-barium-niobium oxide.

2. The article of claim 1 wherein the particles are comprised of a yttrium-barium-ruthenium oxide.

3. The article of claim 2 wherein the high temperature superconductive oxide is a barium copper oxide.

4. The article of claim 2 wherein the high temperature superconductive oxide is a yttrium barium copper oxide.

5. The article of claim 2 wherein the particles have a mean size of about 10 nanometers.

6. The article of claim 2 wherein the particles have sizes from about 5 nanometers to about 100 nanometers.

7. A method of forming a superconductive oxide thin film comprising: depositing a thin film of a high temperature superconductive oxide from (i) precursor materials for said high temperature superconductive oxide and (ii) a ruthenium containing precursor material.

8. The method of claim 7 wherein the ruthenium containing precursor material is ruthenium oxide.

9. The method of claim 7 wherein said deposition is by pulsed laser deposition.

10. The method of claim 7 wherein said superconductive oxide thin film includes particles randomly dispersed therein, said particles comprised of yttrium-barium-ruthenium oxide.

11. The method of claim 7 wherein said superconductive oxide thin film including said ruthenium has flux pinning centers such that said superconductive oxide thin film has a higher critical current within a magnetic field than such a superconductive oxide thin film in the absence of said ruthenium.

12. A method of increasing flux pinning in a high temperature superconductive oxide thin film structure comprising: preparing a thin film of said high temperature superconductive oxide from precursor materials for said high temperature superconductive oxide and a ruthenium containing precursor material.

13. The method of claim 12 wherein the ruthenium containing precursor material is ruthenium oxide.

14. The method of claim 12 wherein said deposition is by pulsed laser deposition.

15. The method of claim 12 wherein said superconductive oxide thin film includes particles randomly dispersed therein, said particles comprised of yttrium-barium-ruthenium oxide.

16. The method of claim 12 wherein said superconductive oxide thin film including said ruthenium has flux pinning centers such that said superconductive oxide thin film has a higher critical current within a magnetic field than such a superconductive oxide thin film in the absence of said ruthenium.
